(19) United States
(12) Patent Application Publication
(10) Pub. No.: US 2025/0357079 A1
(43) Pub. Date: Nov. 20, 2025

(54) MAGNETIZED INDUCTIVELY COUPLED PLASMA PROCESSING DEVICE

(71) Applicant: INNOVATION FOR CREATIVE DEVICES CO., LTD., Anseong-si (KR)

(72) Inventors: Seungho LEE, Yongin-si (KR); Hei Seob JEONG, Seoul (KR); Taeho SHIN, Chungju-si (KR); Bumsoo ON, Yongin-si (KR)

(21) Appl. No.: 19/281,768

(22) Filed: Jul. 28, 2025

Related U.S. Application Data
(63) Continuation of application No. PCT/KR2024/002768, filed on Mar. 5, 2024.

(30) Foreign Application Priority Data
Apr. 3, 2023 (KR) 10-2023-0043782

(51) Int. Cl. H01J 37/32

(52) U.S. Cl. CPC H01J 37/3211; H01J 37/3266

(57) ABSTRACT

A plasma processing device according to one embodiment of the present invention comprises: a chamber having a dielectric window provided in the upper surface thereof; an antenna located above the dielectric window so as to generate plasma in the inner space of the chamber; a substrate holder arranged inside the chamber such that the substrate is mounted thereon; a forward magnetic field generation unit which is arranged outside of the chamber and includes an electromagnet provided outside the chamber between the arrangement surface of the antenna and the arrangement surface of the substrate; a backward magnetic field generation unit, which is arranged below the forward magnetic field generation unit and includes an electromagnet provided outside the chamber between the arrangement surface of the antenna and the arrangement surface of the substrate; and a control unit for controlling current flowing in the forward magnetic field generation unit and current flowing in the backward magnetic field generation unit. The forward magnetic field generation unit forms the magnetic field directed in the forward direction from the antenna toward the substrate, and the backward magnetic field generation unit forms the magnetic field directed in the backward direction from the substrate toward the antenna.

### CROSS-REFERENCE TO RELATED APPLICATIONS

This application is a continuation of and claims priority to PCT/KR2024/002768 filed on Mar. 5, 2024, which claims priority to Korea Patent Application No. 10-2023-0043782 filed on Apr. 3, 2023, the entireties of which are both hereby incorporated by reference.

### TECHNICAL FIELD

The present invention relates to a magnetized inductively coupled plasma (MICP) device and, more particularly, to an MICP device for significantly reducing the damage caused by a magnetic field of a wafer on which circuits are formed.

### BACKGROUND ART

In general, when a magnetic field is applied to inductively coupled plasma (ICP), the loss of electrons to chamber walls may be significantly reduced to increase plasma density. The effect of increasing plasma density becomes larger as the strength of the magnetic field is increased. When a magnetic field is applied, ICP may be maintained even at low pressures to reduce a plasma processing pressure of etching or the like.

When a magnetic field is applied, ICP generating electromagnetic waves using an antenna may generate and propagate various electromagnetic waves, such as Helicon, Circular Wave, R-wave, L-wave, or Polarized Wave, within the plasma. Plasma electromagnetic waves present within the plasma are selected by conditions such as a discharge structure, a magnetic field, or pressure. Characteristics of electromagnetic waves within the plasma are determined through a dispersion relation representing a relationship between the plasma and the electromagnetic waves.

### DISCLOSURE OF THE INVENTION

### Technical Problem

An aspect of the present invention is to significantly reduce irradiation of plasma waves, generated by MICP, to a wafer having circuits.

### Technical Solution

A plasma processing device according to one embodiment of the present invention includes a chamber having a dielectric window provided in an upper surface thereof, an antenna located above the dielectric window to generate plasma in an inner space of the chamber; a substrate holder arranged inside the chamber such that a substrate is mounted thereon; a forward magnetic field generation unit which is arranged outside of the chamber and includes an electromagnet provided outside the chamber between an arrangement surface of the antenna and an arrangement surface of the substrate; a backward magnetic field generation unit which is arranged below the forward magnetic field generation unit and includes an electromagnet provided outside the chamber between the arrangement surface of the antenna and the arrangement surface of the substrate; and a control unit for controlling current flowing in the forward magnetic field generation unit and current flowing in the backward magnetic field generation unit. The forward magnetic field generation unit may generate a magnetic field directed in a forward direction from the antenna toward the substrate; and the backward magnetic field generation unit may generate a magnetic field directed in a backward direction from the substrate toward the antenna.

In one embodiment of the present invention, the control unit may decrease an absolute value of the magnetic field to a first point in the backward direction with respect to a center of the substrate, and the control unit may increase the absolute value of the magnetic field in the backward direction from the first point.

In one embodiment of the present invention, the forward magnetic field generation unit may include a first electromagnet and a second electromagnet spaced apart from each other, and the backward magnetic field generation unit may include a third electromagnet.

In one embodiment of the present invention, a diameter D1 of an electromagnet constituting the forward magnetic field generation unit may be larger or smaller than a diameter D3 of an electromagnet constituting the backward magnetic field generation unit.

In one embodiment of the present invention, the control unit may control a ratio of a product of current and a number of coil turns (I1×N1+I2×N2) of an electromagnet constituting the forward magnetic field generation unit to a product of current and a number of coil turns (I3×N3) of an electromagnet constituting the backward magnetic field generation unit to be within a range of 1:0.5 to 1:0.9.

In one embodiment of the present invention, the plasma processing device may further include an auxiliary electromagnet disposed at a position lower than an upper surface of the substrate holder, and the control unit may control current of the auxiliary electromagnet.

In one embodiment of the present invention, a direction of a magnetic field generated by the auxiliary electromagnet may be a forward direction.

In one embodiment of the present invention, the auxiliary electromagnet may include at least one of: a first auxiliary electromagnet disposed outside the chamber between the upper surface and a lower surface of the substrate holder; a second auxiliary electromagnet embedded in the substrate holder; and a third auxiliary electromagnet disposed outside the chamber at a position lower than the lower surface of the substrate holder.

In one embodiment of the present invention, the control unit may control a ratio of a product of current and a number of coil turns (I3×N3) of an electromagnet constituting the backward magnetic field generation unit to a product of current and a number of coil turns (I4×N4) of the auxiliary electromagnet to be within a range of 1:0.01 to 1:0.3.

In one embodiment of the present invention, strength of the magnetic field in a space between the dielectric window and the upper surface of the substrate holder may be 10 Gauss or less from a central axis of the substrate holder to the first point.

A plasma processing device according to one embodiment of the present invention includes a chamber having a dielectric window provided in on an upper surface thereof, a grid dividing an inner space of the chamber into an upper region and a lower region and extracting plasma from an upper region to a lower region; an antenna located above the dielectric window to generate plasma in an inner space of the chamber; a substrate holder arranged inside the chamber such that a substrate is mounted thereon; a forward magnetic field generation unit including an electromagnet installed outside the chamber between an arrangement surface of the antenna and an arrangement surface of the substrate; a backward magnetic field generation unit arranged below the forward magnetic field generation unit and including an electromagnet installed outside the chamber between the arrangement surface of the antenna and the arrangement surface of the substrate; and a control unit controlling current flowing through the forward magnetic field generation unit and current flowing through the backward magnetic field generation unit. The forward magnetic field generation unit may generate a magnetic field directed in a forward direction from the antenna toward the substrate, and the backward magnetic field generation unit may generate a magnetic field directed in a backward direction from the substrate toward the antenna.

In one embodiment of the present invention, the control unit may decrease an absolute value of the magnetic field to a first point in the backward direction with respect to a center of the substrate, and the control unit may increase the absolute value of the magnetic field in the backward direction from the first point.

In one embodiment of the present invention, an arrangement surface of the grid may be located at a position higher toward the dielectric window than the first point that is a region (or a point) in which the magnetic field is zero.

### Advantageous Effects

MICP with an electromagnet coil generating a magnetic field according to one embodiment of the present invention may serve to increase plasma density by heating plasma through induction heating and wave heating in a plasma generation space. When characteristics of the magnetic field facilitating propagation of R-waves are changed, R-waves are unable to smoothly propagate toward a substrate and are reflected at a portion at which the characteristics of the magnetic field are changed. A reflection function of the electromagnetic waves may significantly reduce damage to a wafer with a circuit caused by R-waves. The reflected R-waves may propagate backward to a plasma generation space to help plasma heating.

### BRIEF DESCRIPTION OF THE DRAWINGS

FIG. 1 a graph illustrating a dispersion relation of plasma characteristics when directions of a magnetic field and electromagnetic waves within MICP are the same, according to the present invention.

FIG. 2 is a conceptual diagram illustrating a plasma processing device according to one embodiment of the present invention.

FIG. 3 is a conceptual diagram illustrating a plasma processing device according to another embodiment of the present invention.

FIG. 4A is a computational simulation result illustrating a magnetic field distribution of a plasma processing device according to another embodiment of the present invention.

FIG. 4B is a graph illustrating the strength of a magnetic field along a z-axis based on the computational simulation result of FIG. 4A.

FIG. 5A is a computational simulation result illustrating a magnetic field distribution of a plasma processing device according to another embodiment of the present invention.

FIG. 5B is a graph illustrating the strength of a magnetic field along a z-axis based on the computational simulation result of FIG. 5A.

FIG. 5C is a graph illustrating the strength of a magnetic field with a radius based on the computational simulation result of FIG. 5A.

FIG. 6A is a computational simulation result illustrating a magnetic field distribution of a plasma processing device according to another embodiment of the present invention.

FIG. 6B is a graph illustrating a magnetic field line along a z-axis based on the computational simulation result of FIG. 6A.

FIG. 6C is a graph illustrating the strength of a magnetic field along the z-axis based on the computational simulation result of FIG. 6A.

FIG. 7A is a computational simulation result illustrating a magnetic field distribution of a plasma processing device according to another embodiment of the present invention.

FIG. 7B is a graph illustrating the strength of a magnetic field with a radius based on the computational simulation result of FIG. 7A.

FIG. 8A is a computational simulation result illustrating a magnetic field distribution of a plasma processing device according to another embodiment of the present invention.

FIG. 8B is a graph illustrating the strength of a magnetic field along a z-axis based on the computational simulation result of FIG. 8A.

FIG. 8C is a graph illustrating the strength of a magnetic field with a radius based on the computational simulation result of FIG. 8A.

FIG. 9A is a computational simulation result illustrating a magnetic field distribution of a plasma processing device according to another embodiment of the present invention.

FIG. 9B is a graph illustrating the strength of a magnetic field along a z-axis based on the computational simulation result of FIG. 9A.

### MODE FOR CARRYING OUT THE INVENTION

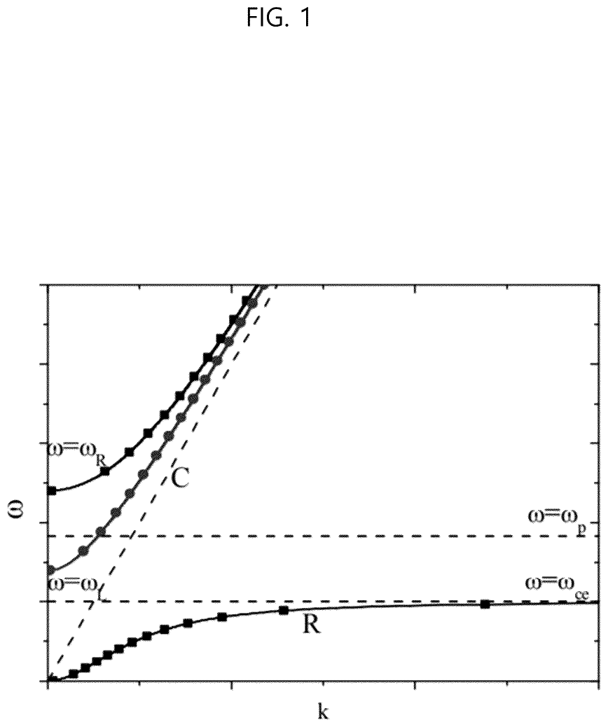

FIG. 1 a graph illustrating a dispersion relation of plasma characteristics when directions of a magnetic field and electromagnetic waves within MICP are the same, according to the present invention.

For example, referring to a dispersion relation when a propagation direction of electromagnetic waves generated by an antenna supplied with RF power of 27.12 MHz is parallel to a magnetic field direction, ω (an angular frequency corresponding to 27.12 MHz)<ω_{CE} (a cyclotron angular frequency of electron) condition may be satisfied. Therefore, only R-waves may be present at 27.12 MHz. Other than plasma induction heating caused by an induced electric field of an antenna, plasma heating caused by electromagnetic waves may be performed only through R-wave absorption (or heating). When a magnetic field (9.7 Gauss) corresponding to an electron gyro-frequency of 27.12 MHz is generated, a wave heating effect caused by R-waves may occur.

However, when electromagnetic waves propagating through plasma reach a substrate with circuits, an antenna effect occurring during a polysilicon gate etch process may severely damage the circuits.

In addition, a strong electric field caused by a bias voltage applied to a substrate may induce arcs or micro-arcs in a semiconductor etching apparatus. The bias voltage may cause significant damage to circuits on a wafer during a process of forming components and circuits of the etching apparatus. In such a strong electric field in which arcs may easily occur, when an electric field of RF electromagnetic waves affects circuits formed on a wafer, the risk of damage to the circuits may further increase. In addition, when a strong magnetic field is present, the risk of occurrence of micro-arcs, or the like, may increase due to charge concentration caused by the Hall effect.

Plasma electromagnetic waves incident on the substrate may cause damage to circuits of the wafer due to a magnetic field of the MICP and the strong bias voltage applied to the substrate. Significant factors, which may cause circuit damage, include a substrate bias voltage, plasma electromagnetic waves near the substrate, strong magnetic fields near the substrate, or the like.

The substrate bias voltage is a main factor for increasing an etch rate (ER), which is the primary purpose of MICP. However, plasma electromagnetic waves and strong magnetic fields near the substrate are unnecessary for etching.

Therefore, the present invention proposes a method of significantly reduce plasma waves and strong magnetic fields near the substrate.

According to an embodiment of the present invention, the present inventor proposes a method of reducing the strength of a magnetic field to a significantly low magnetic field near a substrate using an electromagnet generating a forward magnetic field and an electromagnet generating a backward magnetic field, as well as a method of reducing the strength of a magnetic field at both a center and edges of a substrate using an auxiliary electromagnet.

The present inventor proposes a method of generating a cusp field near the substrate as a method of significantly reducing electromagnetic waves generated by the RF antenna and plasma near the substrate. A scheme to increase plasma density in ICP or capacitively coupled plasma (CCP) is to increase an RF frequency. To increase plasma density, a frequency applied to the ICP antenna may be increased to 13.56 MHz, 27.12 MHz, or 54 MHz. However, in an RF frequency range of tens of MHz, the only electromagnetic wave, capable of propagating in plasma in a direction parallel to a magnetic field, is R-wave.

For electron cyclotron resonance, the strength of a magnetic field corresponding to 27.12 MHz is 9.7 Gauss. In this case, the magnetic field of the magnetic field strength at the center of the plasma discharge space may be around 10 to 20 Gauss. For electron cyclotron resonance at 54 MHz, the strength of the magnetic field is 19.4 Gauss. In this case, the strength of the magnetic field at the center of the plasma discharge space may be around 20 to 40 Gauss.

In the present invention, with respect to a propagation direction of electromagnetic waves generated in plasma by an antenna, a direction toward a substrate is defined as a forward direction and an opposite direction is defined as a backward direction. Additionally, a positive Z-axis is set to extend from the substrate to a dielectric window and an upper surface of the substrate is Z=0. Furthermore, a radius from the substrate center to an inner wall of a chamber is denoted as R and a center of the substrate is denoted as R=0.

Hereinafter, example embodiments of the present invention may, however, be embodied in many different forms and should not be construed as being limited to the embodiments set forth herein. Rather, the embodiments are provided so that the present invention will be thorough and complete, and will fully convey the concept of example embodiments to those of ordinary skill in the art. In the drawings, components are exaggerated for clarity. Like reference numerals in the drawings denote like elements and, therefore, repetitive description thereof will be omitted.

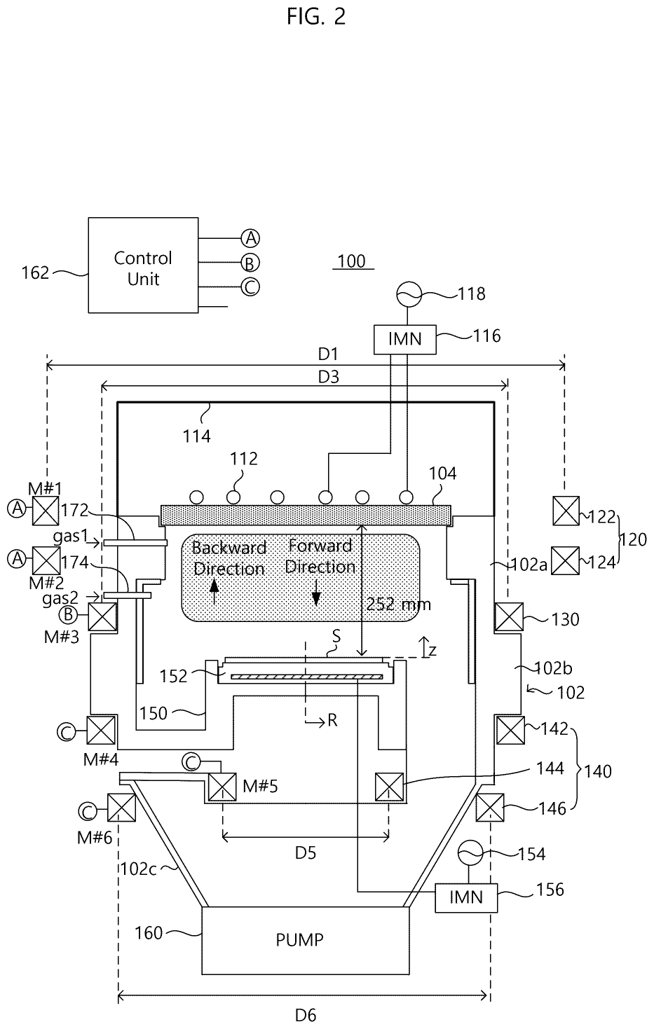

FIG. 2 is a conceptual diagram illustrating a plasma processing device according to one embodiment of the present invention.

Referring to FIG. 2, a plasma processing device 100 according to one embodiment of the present invention comprises: a chamber 102 having a dielectric window 104 provided in the upper surface thereof, an antenna 112 located above the dielectric window 104 so as to generate plasma in the inner space of the chamber 102; a substrate holder 150 arranged inside the chamber 102 such that the substrate S is mounted thereon; a forward magnetic field generation unit 120 which is arranged outside of the chamber 102 and includes an electromagnet provided outside the chamber 102 between the arrangement surface of the antenna 112 and the arrangement surface of the substrate S; a backward magnetic field generation unit 130, which is arranged below the forward magnetic field generation unit 120 and includes an electromagnet provided outside the chamber between the arrangement surface of the antenna and the arrangement surface of the substrate; and a control unit 162 for controlling current flowing in the forward magnetic field generation unit 120 and current flowing in the backward magnetic field generation unit 130.

The forward magnetic field generation unit 120 forms the magnetic field directed in the forward direction from the antenna toward the substrate, and the backward magnetic field generation unit 130 forms the magnetic field directed in the backward direction from the substrate toward the antenna.

The chamber 102 may be a cylindrical metal chamber or a cylindrical metal chamber with an insulated surface. The chamber 102 may be divided into an upper chamber 102a, a middle chamber 102b, and a lower chamber 102c. An inner diameter of the upper chamber 102a may be smaller than that of the middle chamber 102b. The lower chamber 102c may have a tapered shape with a decreasing diameter. The chamber 102 is open at its upper surface, and the dielectric window 104 may be disposed on the upper surface of the chamber. A first gas inlet 172 may be arranged on a side surface of the upper chamber 102a to receive a first gas. A second gas inlet 174 may be arranged on a side surface of the middle chamber 102b to supply a second gas. A vacuum pump 160 or a pipe connected to a vacuum pump may be disposed on a lower surface of the lower chamber 102c to evacuate the chamber.

The dielectric window 104 may be made of a disk-shaped dielectric material, such as quartz, alumina, or sapphire. The dielectric window 104 may encapsulate the chamber and allow electromagnetic waves or induced electric fields, generated by the antenna 112, to pass therethrough.

The antenna 112 may be located above the dielectric window 104. The antenna 112 may be an antenna having a spiral coil structure or a multilayer structure formed of a conductive material. Current flowing through the antenna 112 may generate a time-varying magnetic field, and the time-varying magnetic field may generate an induced electric field or electromagnetic waves inside the chamber. The antenna 112 may be cooled by a refrigerant flowing through the inside thereof.

The antenna housing 114 may shield and reflect electromagnetic waves radiated from the antenna 112. The antenna housing 114 may have a cylindrical structure formed of a conductive material.

The impedance matching network (IMN) 116 may include variable reactive elements and may transfer power from an RF power supply 118 to the antenna 112.

The RF power supply 118 may supply RF frequency power to the antenna 112 through the impedance matching network 116. The frequency of the RF power supply 118 may range from a few MHz to tens of MHz.

The substrate S may be a semiconductor substrate or a glass substrate. The substrate S may be a silicon wafer.

The substrate holder 150 may hold the substrate S. The substrate holder 150 may include an electrostatic chuck 152, and the electrostatic chuck may hold the substrate using electrostatic force. The substrate holder 150 may include an RF electrode, and a bias RF power supply 154 may supply RF power to the RF electrode through an impedance matching network 156. The bias RF power supply 154 may apply a bias voltage to the substrate S to accelerate ions from plasma.

The forward magnetic field generation unit 120 may include a first electromagnet 122 and a second electromagnet 124 spaced apart from each other. The first electromagnet 122 may be disposed substantially in the same plane as the dielectric window. The first electromagnet 122 may generate a magnetic field in the forward direction (a negative z-axis). The second electromagnet 124 may have the same structure as the first electromagnet and may be disposed below the first electromagnet 122. Both the first electromagnet 122 and the second electromagnet 124 may generate a magnetic field in the forward direction (the negative z-axis). The first electromagnet 122 and the second electromagnet 124 may be connected in series. A diameter of the first electromagnet 122 and the second electromagnet 124 is D1, which may be larger than an outer diameter of the chamber. The first current flowing through the first electromagnet 122 is I1, and the number of turns is N1. Magnetic motive force is represented as the product of current and the number of turns. The magnetic motive force of the forward magnetic field generation unit 120 is equal to the sum of the magnetic motive force of the first electromagnet (I1×N1) and the magnetic motive force of the second electromagnet (I2×N2).

The backward magnetic field generation unit 130 may include a third electromagnet M #3. The backward magnetic field generation unit 130 may generate a magnetic field in a backward direction (a positive z-axis). A diameter D3 of the third electromagnet M #3 may be smaller than the diameter D1 of the first electromagnet 122. Alternatively, the diameter D3 of the third electromagnet M #3 may be larger than the diameter D1 of the first electromagnet 122. The magnetic motive force (I3×N3) of the backward magnetic field generation unit 130 is equal to the product of the third current 13 flowing through the third electromagnet and the number of turns N3.

The forward magnetic field generation unit 120 and the backward magnetic field generation unit 130 may reduce the strength of a magnetic field at the upper surface of the substrate S.

The control unit 162 may decrease an absolute value of the magnetic field up to a first point in the backward direction with respect to the center of the substrate S, and increase the absolute value of the magnetic field in the backward direction from the first point. For example, a cusp field may be generated between the substrate S and the dielectric window 104. The cusp field may be generated by a pair of magnetic fields in opposite directions. The cusp field may provide a region (or a point) in which the magnetic field is zero. The first point may be the region (or the point) in which the magnetic field is zero. The region, in which the magnetic field is zero, may be disposed close to the substrate S. Preferably, the position where the magnetic field is zero may be between 60 mm and 100 mm with respect to the center of the substrate S. A portion of the electromagnetic waves generated by the antenna 112 may be absorbed for inductive heating below the dielectric window 104 to generate inductively coupled plasma, while the remaining electromagnetic waves may propagate through the plasma. The electromagnetic waves propagating through the plasma may be reflected at the position at which the magnetic field is zero. To this end, the position at which the magnetic field is zero may be between 60 mm and 100 mm with respect to the center of the substrate S.

The diameter D1 of the electromagnet constituting the forward magnetic field generation unit 120 may be larger than the diameter D3 of the electromagnet constituting the backward magnetic field generation unit 130. Such a structure may improve the radial characteristics of a magnetic field.

The diameter D1 of the electromagnet constituting the forward magnetic field generation unit 120 may be larger than the diameter D3 of the electromagnet constituting the backward magnetic field generation unit 130. Such a structure may improve the radial characteristics of a magnetic field.

The control unit 162 may control a ratio of the product of the current and the number of coil turns of the electromagnet constituting the forward magnetic field generation unit 120 (I1×N1+I2×N2) to the product of the current and the number of coil turns of the electromagnet constituting the backward magnetic field generation unit (130 I3×N3) to be within the range of 1:0.5 to 1:0.9.

The auxiliary electromagnet 140 may be disposed at a position lower than the upper surface of the substrate holder 150. The control unit 162 may control current of the auxiliary electromagnet 140. A direction of a magnetic field generated by the auxiliary electromagnet 140 may be in the forward direction (negative z-direction). The auxiliary electromagnet 140 may mainly modify a radial magnetic field distribution.

The auxiliary electromagnet 140 may include at least one of: a first auxiliary electromagnet 142 disposed outside the chamber between the upper surface of the substrate holder 150 and the lower surface of the substrate holder 152; a second auxiliary electromagnet 144 embedded in the substrate holder; and a third auxiliary electromagnet 146 disposed outside the chamber at a position lower than the lower surface of the substrate holder.

The first auxiliary electromagnet 142 may improve the uniformity of the radial magnetic field distribution. A diameter of the first auxiliary electromagnet 142 may be the same as the diameter D3 of the electromagnet constituting the backward magnetic field generation unit 130.

The second auxiliary electromagnet 144 may be disposed inside the substrate holder, which is mechanically complex but enables precise control of local magnetic field distribution. A diameter D5 of the second auxiliary electromagnet 144 may be smaller than the diameter D3 of the electromagnet constituting the backward magnetic field generation unit 130.

The third auxiliary electromagnet 146 may be disposed outside the chamber at a position lower than the lower surface of the substrate holder, which is mechanically simple. A diameter D6 of the third auxiliary electromagnet 146 may be smaller than the diameter D3 of the electromagnet constituting the backward magnetic field generation unit 130.

The control unit 162 may control a ratio of the product of current and the number of turns of the electromagnet constituting the backward magnetic field generation unit (130 I3×N3) to the product of the current and the number of turns of the auxiliary electromagnet (140 I4×N4) to be within the range of 1:0.01 to 1:0.3. The auxiliary electromagnet 140 may precisely adjust the radial magnetic field distribution locally rather than controlling the overall z-axis magnetic field distribution.

The strength of the magnetic field in a space between the dielectric window 104 and the upper surface of the substrate holder 150 may be 10 Gauss or less from the central axis of the substrate holder to the first point.

That is, the control unit 162 may control the ratio of the product of the current and the number of coil turns of the electromagnet constituting the forward magnetic field generation unit (120 I1×N1+I2×N2) to the product of the current and the number of coil turns of the electromagnet constituting the backward magnetic field generation unit (130 I3×N3) to be within the range of 1:0.5 to 1:0.9.

The control unit 162 may control the currents of the forward magnetic field generation unit 120, the backward magnetic field generation unit 130, and the auxiliary electromagnet 140 to control a magnetic field distribution. For example, the control unit 162 may control a magnetic field of zero to be disposed at a position 60 mm from the substrate S to 100 mm. In addition, the control unit 162 may control the current of the auxiliary electromagnet 140, allowing the strength of the magnetic field to be uniform to 80 nm from the center of the substrate S.

When a pressure of the MICP device is higher than a typical process pressure of ICP, the uniformity of the plasma may decrease. However, when the pressure of the MICP device is 3 mTorr (or 5 mTorr) or less, a gas flow enters a molecular flow regime in which diffusion is dominant. Accordingly, a supplied etching gas mixture or generated plasma may diffuse rapidly. When a process is performed at a low pressure of 3 mTorr or less using MICP, MICP may provide higher spatial uniformity than ICP or CCP.

According to an embodiment of the present invention, the plasma processing device may generate plasma at a pressure of 5 mTorr or less. The plasma processing device may also generate plasma at a pressure of 1 mTorr or less.

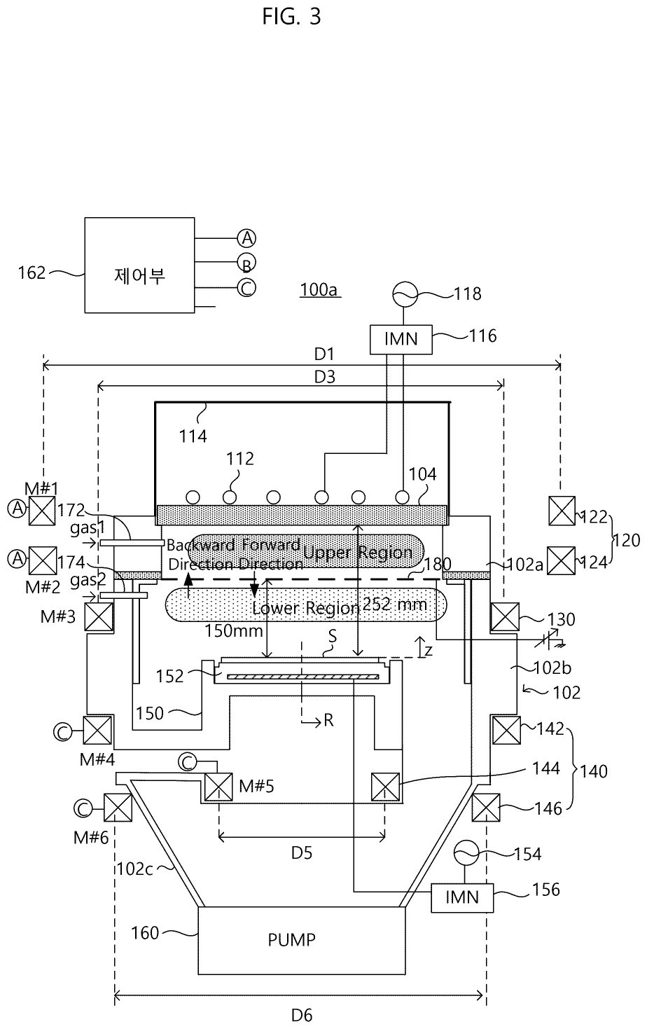

FIG. 3 is a conceptual diagram illustrating a plasma processing device according to another embodiment of the present invention.

Referring to FIG. 3, a plasma processing device 100a according to one embodiment of the present invention includes: a chamber 102 having a dielectric window 104 provided in on an upper surface thereof, a grid 180 dividing an inner space of the chamber into an upper region and a lower region and extracting plasma from an upper region to a lower region; an antenna 112 located above the dielectric window 104 so as to generate plasma in the inner space of the chamber; a substrate holder 150 arranged inside the chamber such that a substrate is mounted thereon; a forward magnetic field generation unit 120 including an electromagnet installed outside the chamber between an arrangement surface of the antenna 112 and an arrangement surface of the substrate S; a backward magnetic field generation unit 130 arranged below the forward magnetic field generation unit 120 and including an electromagnet installed outside the chamber between the arrangement surface of the antenna and the arrangement surface of the substrate; and a control unit 162 controlling current flowing through the forward magnetic field generation unit 120 and current flowing through the backward magnetic field generation unit 130. The forward magnetic field generation unit 120 generates a magnetic field directed in the forward direction from the antenna toward the substrate, and the backward magnetic field generation unit 130 generates a magnetic field directed in the backward direction from the substrate toward the antenna.

The plasma processing device 100a may perform atomic layer etch. The plasma processing device 100a may include a self-limiting adsorption reaction step and an etching step of an etchant.

The control unit 162 may decrease an absolute value of the magnetic field to a first point in the backward direction with respect to a center of the substrate and increase the absolute value of the magnetic field in the backward direction from the first point. The first point may be disposed below the arrangement surface of the grid 180.

The chamber 102 may be divided into an upper chamber 102a, a middle chamber 102b, and a lower chamber 102c. The grid 180 may be mounted at a bonding portion between the upper chamber and the middle chamber. The grid 180 may separate the upper region thereabove from the lower region therebelow. A position of the grid 180 may be adjusted based on a magnetic field distribution.

The antenna 112 may generate high-density inductively coupled plasma in the upper region. The grid 180 may extract plasma from the upper region to the lower region. The grid 180 may be a perforated plate or mesh. When a negative bias voltage is applied to the grid 180, the grid 180 may form an energy barrier to extract high-energy electrons to the lower region. As the extracted electrons collide with neutral gas in the lower region, they generate plasma while losing energy, and thus plasma with low electron temperature may be generated in the lower region.

The grid 180 may include a first grid disposed thereabove and a second grid disposed therebelow. When a negative bias voltage is applied to the first grid and a positive bias voltage is applied to the second grid, positive ions are unable to pass through the lower region due to an energy barrier formed by the second grid, while only high-energy electrons may pass through an energy barrier of the first grid. With the voltage applied to the grid 180, the self-limiting adsorption reaction step and the etching step of the etchant may be distinguished from each other. In the adsorption reaction step, a first process gas may be supplied through a first gas inlet, the antenna may generate plasma in the upper region, and the etchant that is active species may pass through the grid to the lower region. In the etching step, a second process gas may be supplied through the second gas inlet, the antenna may generate plasma in the upper region, and ions and/or electrons may pass through the grid 180 to the lower region.

The grid 180 may include a plurality of grid layers, and the plasma characteristics in the lower region may be adjusted by controlling a voltage applied to each of the grid layers. For example, the grid 180 may include a sequentially stacked floating grid, an electron or ion repelling grid, and an electron/ion energy control grid.

The lower region below the grid 180 has a significant effect on etching. The grid 180 may extract electrons and/or ions from the upper region, in which plasma is generated, to the lower region, and then the extracted electrons may ionize an etching gas. The plasma in the lower region may provide a low plasma potential due to low electron temperature thereof

In the lower region, ions may be accelerated by an electric field, generated by an RF bias of the substrate, to vertically impinge on the substrate. In the lower region, ions may provide physical etching.

However, when the strength of the magnetic field in the lower region is high, ions rotate with a Larmor radius due to the magnetic field. The electric field generated by the RF bias of the substrate accelerates the ions toward the substrate, but the ions are affected by magnetic field-induced rotation to obliquely impinge on the substrate. In this case, it may be difficult to achieve desired etching characteristics or etching uniformity. The degree to which the ion motion direction is bent decreases as the Larmor radius increases. Accordingly, the strength of the magnetic field near the substrate is preferably maintained to be sufficiently low at 10 Gauss or below.

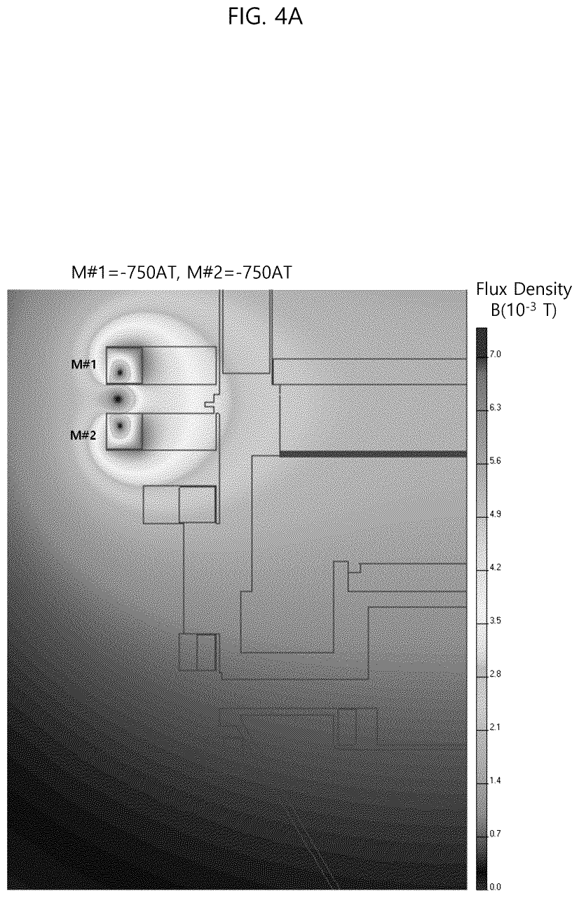

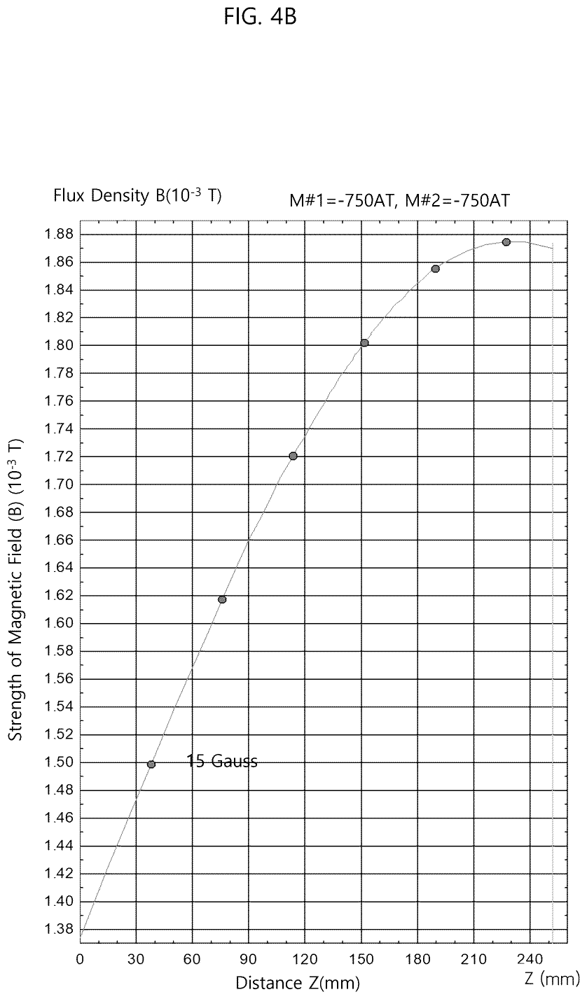

FIG. 4A is a computational simulation result illustrating a magnetic field distribution of a plasma processing device according to another embodiment of the present invention.

FIG. 4B is a graph illustrating the strength of a magnetic field along a z-axis based on the computational simulation result of FIG. 4A.

Referring to FIGS. 4A and 4B, the magnetic motive force (the product of current and the number of turns) of a first electromagnet (122) M #1 is −750 amperes (A), and the magnetic motive force (the product of current and the number of turns) of a second electromagnet (124) M #2 is −750 amperes (A). The forward magnetic field generation unit 120 includes the first electromagnet (122) M #1 and the second electromagnet (124) M #2 and generates a forward magnetic field.

According to a modified embodiment of the present invention, when a radius of the first electromagnet (122) M #1 and a radius the second electromagnet (124) M #2 are increased, a value of a magnetic field is unchanged in an axis due to the characteristics of a Helmholtz coil. However, changing the radii of the electromagnet coils leads to a slight change in the magnetic field near a chamber wall. The radius of the first electromagnet (122) M #1 and the radius the second electromagnet (124) M #2 may be adjusted to optimize the magnetic field at edges of a substrate.

The strength of the magnetic field ranges from 13.7 to 17.9 Gauss G from the substrate to 150 mm. The strength of the magnetic field near the substrate is 13.7 G. In an upper region that is a plasma generation space, the strength of a strong magnetic field helps significant reduction in plasma loss and generation of plasma, playing a primary role in increasing plasma density. However, when the strength of the magnetic field directly above the substrate is high, wafers having fine and complex circuits placed on the substrate may be damaged by the magnetic field.

Therefore, a backward magnetic field generation unit may be used to reduce the strength of the magnetic field directly above the substrate.

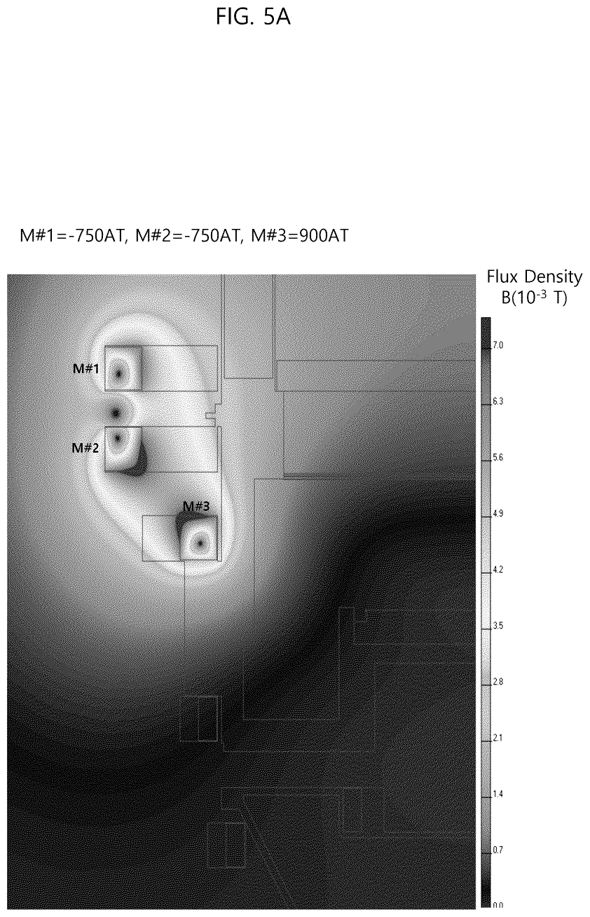

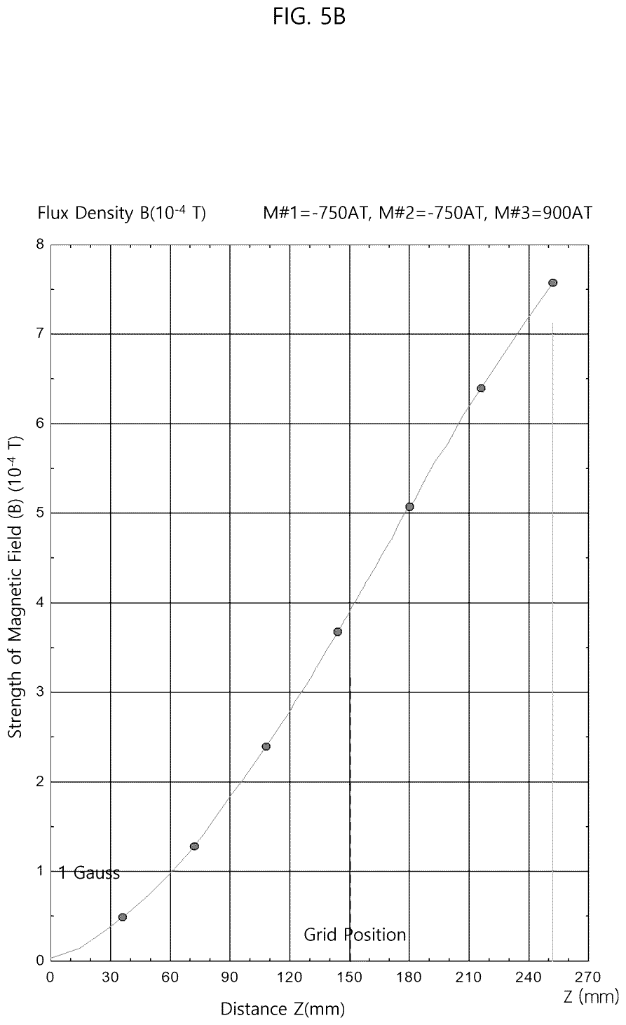

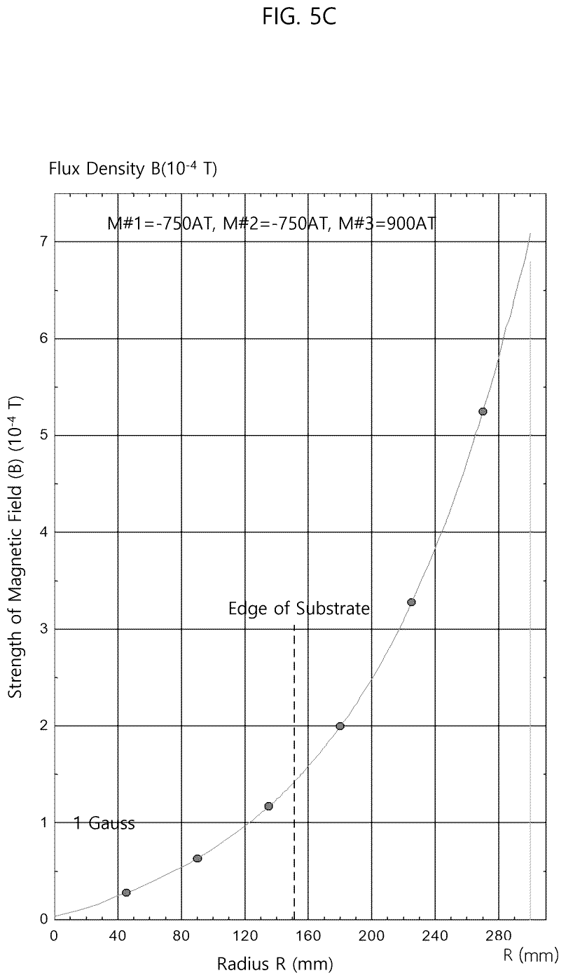

FIG. 5A is a computational simulation result illustrating a magnetic field distribution of a plasma processing device according to another embodiment of the present invention.

FIG. 5B is a graph illustrating the strength of a magnetic field along a z-axis based on the computational simulation result of FIG. 5A.

FIG. 5C is a graph illustrating the strength of a magnetic field with a radius based on the computational simulation result of FIG. 5A.

Referring to FIGS. 5A to 5C, a forward magnetic field generation unit 120 includes a first electromagnet (122) M #1 and a second electromagnet (124) M #2 and generates a forward magnetic field. The magnetic motive force (the product of current and the number of turns) of the first electromagnet (122) M #1 is −750 amperes (A), and the magnetic motive force (the product of current and the number of turns) of the second electromagnet (124) M #2 is −750 amperes (A).

A backward magnetic field generation unit 130 includes a third electromagnet (130) M #3 and generates a backward magnetic field. The magnetic motive force (the product of current and the number of turns) of the third electromagnet (130) M #3 is 900 amperes (A).

When the backward magnetic field generation unit 130 generates a backward magnetic field, the strength of the magnetic field ranges from 0.1 to 4.0 Gauss G from the substrate to 150 mm. It can be seen that the strength of the magnetic field near the substrate is 0.1 G, nearly zero. The risk of damage caused by the magnetic field is reduced. The strength of the magnetic field is 1.5 G at the edge of the substrate (R=150 mm).

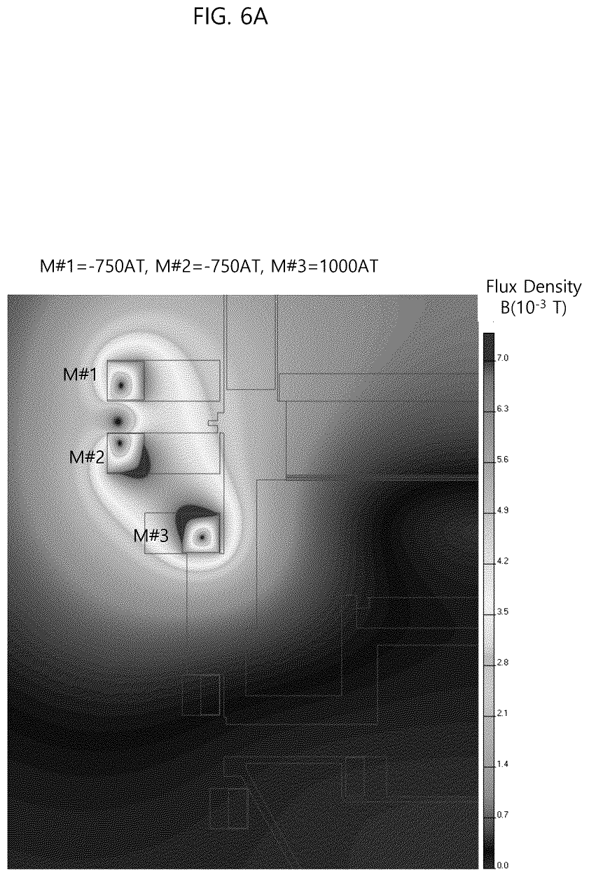

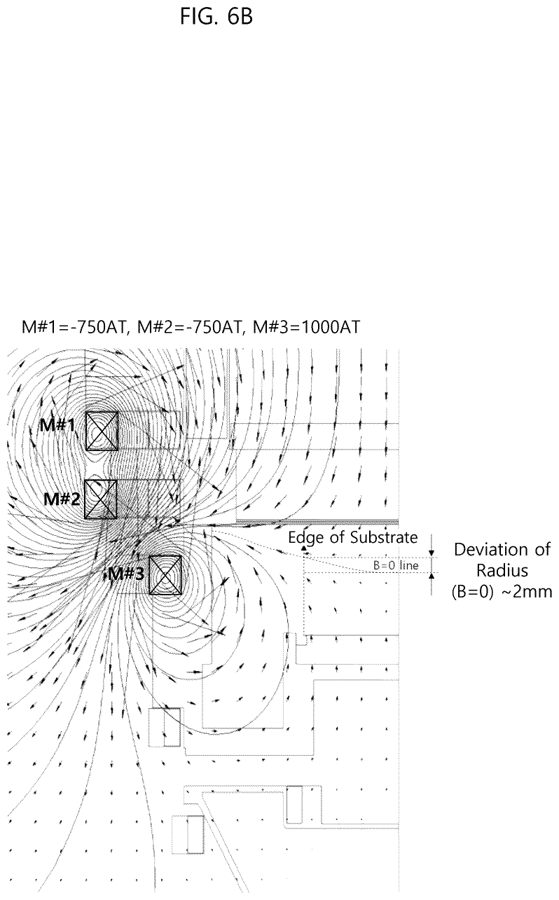

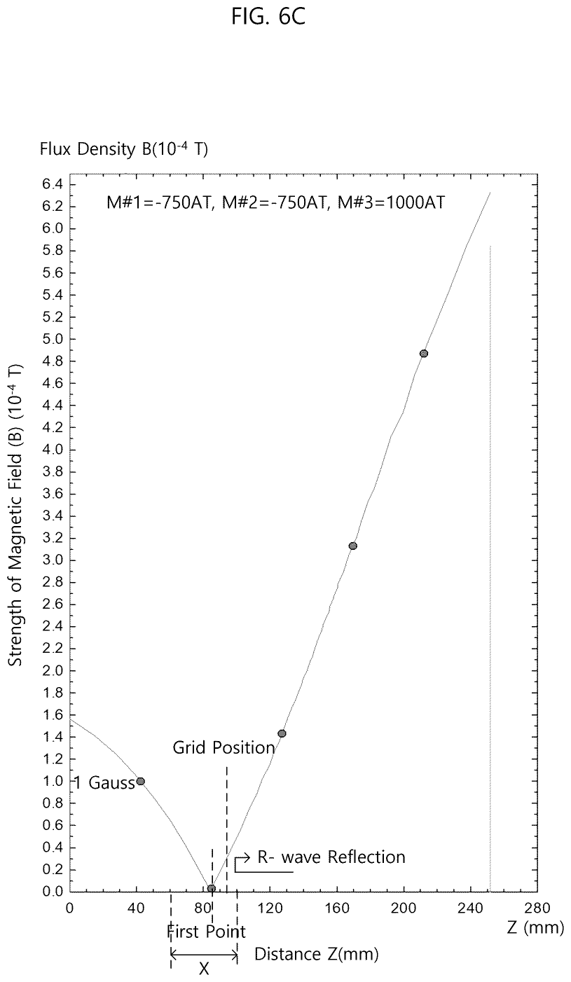

FIG. 6A is a computational simulation result illustrating a magnetic field distribution of a plasma processing device according to another embodiment of the present invention.

FIG. 6B is a graph illustrating a magnetic field line along a z-axis based on the computational simulation result of FIG. 6A.

FIG. 6C is a graph illustrating the strength of a magnetic field along the z-axis based on the computational simulation result of FIG. 6A.

Referring to FIGS. 6A to 6C, a forward magnetic field generation unit 120 includes a first electromagnet (122) M #1 and a second electromagnet (124) M #2 and generates a forward magnetic field. The magnetic motive force (the product of current and the number of turns) of the first electromagnet (122) M #1 is −750 amperes (A), and the magnetic motive force (the product of current and the number of turns) of the second electromagnet (124) M #2 is −750 amperes (A).

A backward magnetic field generation unit 130 includes a third electromagnet (130) M #3 and generates a backward magnetic field. The magnetic motive force (the product of current and the number of turns) of the third electromagnet (130) M #3 is 1000 amperes (A).

When the backward magnetic field generation unit 130 generates a backward magnetic field, the strength of the magnetic field ranges from 0.0 to 2.3 G from the substrate to 150 mm. The strength of the magnetic field near the substrate is 0 G. The risk of damage caused by the magnetic field is reduced.

A cusp field is formed, and a value of R-wave that is not absorbed in the upper region and reach the substrate may be significantly reduced. The R-wave may smoothly propagate from the dielectric window (Z=252 mm) to Z=83 mm to perform plasma heating. However, the R-wave is reflected from the moment it passes Z=83 mm.

The control unit 162 may decrease an absolute value of the magnetic field to a first point in a backward direction from the center of the substrate and increase the absolute value of the magnetic field in the backward direction from the first point. For example, a cusp field may be generated between the substrate and the dielectric window. The cusp field may be generated by a pair of magnetic fields in opposite directions. The cusp field may provide a region (or a point) in which the magnetic field is zero. The first point may be a region (or a point) in which the magnetic field is zero. The region, in which the magnetic field is zero, may be disposed close to the substrate. The position, in which the magnetic field is zero, may be preferably 100 mm from the substrate with respect to the center of the substrate

The grid 180 may be disposed to be higher toward the antenna direction than the first point.

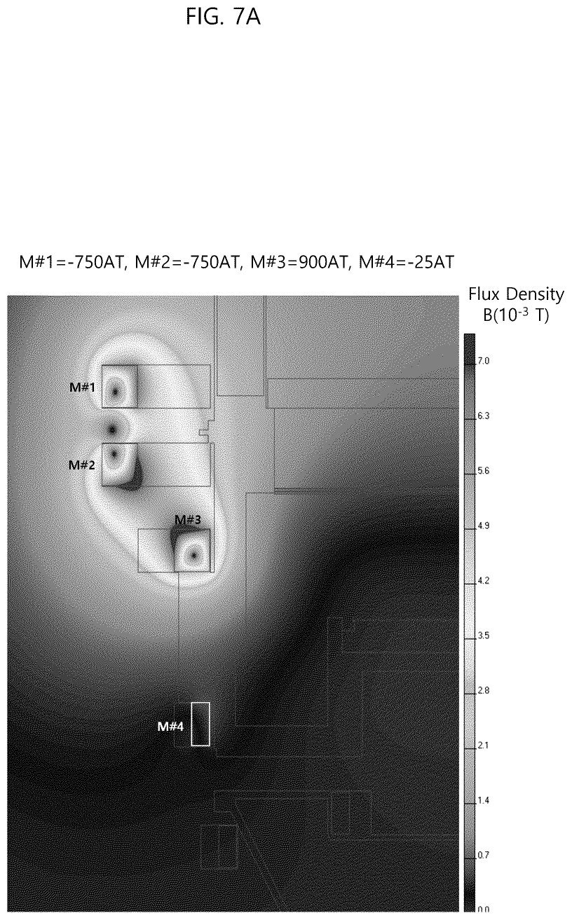

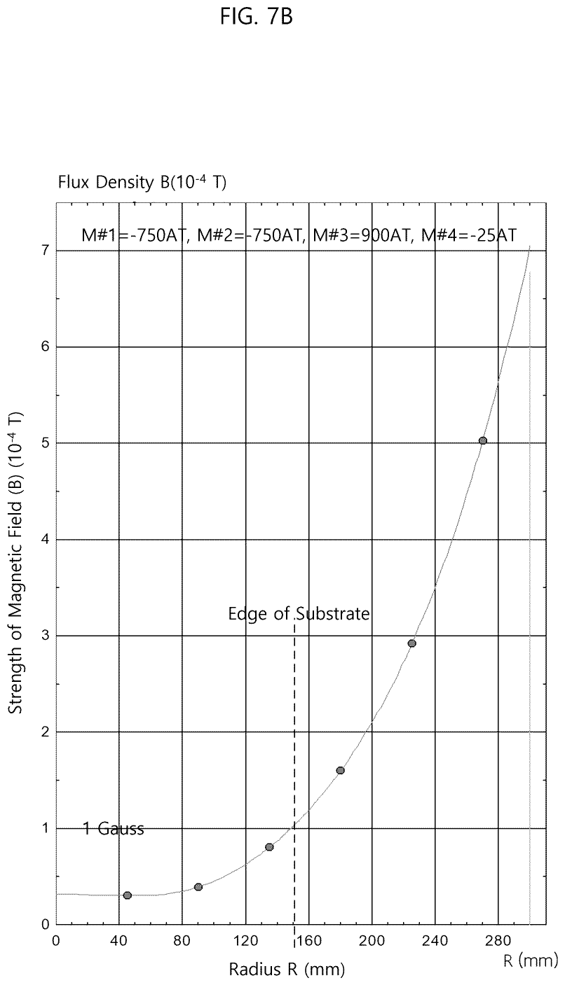

FIG. 7A is a computational simulation result illustrating a magnetic field distribution of a plasma processing device according to another embodiment of the present invention.

FIG. 7B is a graph illustrating the strength of a magnetic field with a radius based on the computational simulation result of FIG. 7A.

Referring to FIGS. 7A and 7B, a forward magnetic field generation unit 120 includes a first electromagnet (122) M #1 and a second electromagnet (124) M #2 and generates a forward magnetic field. The magnetic motive force (the product of current and the number of turns) of the first electromagnet (122) M #1 is −750 amperes (A), and the magnetic motive force (the product of current and the number of turns) of the second electromagnet (124) M #2 is −750 amperes (A).

A backward magnetic field generation unit 130 includes a third electromagnet M #3 and generates a backward magnetic field. The magnetic motive force (the product of current and the number of turns) of the third electromagnet M #3 is 900 amperes (A).

An auxiliary electromagnet 140 may include a first auxiliary electromagnet (142) M #4 disposed outside a chamber between an upper surface of a substrate holder and a lower surface of the substrate holder. The auxiliary electromagnet 140 may generate a forward magnetic field. The magnetic motive force (the product of current and the number of turns) of the first auxiliary electromagnet (142) M #4 is 25 amperes (A).

When the first auxiliary electromagnet (142) M #4 is added, the strength of a magnetic field ranges from 0.26 to 1.05 G from the substrate to edges of the substrate at 150 mm. A variation between the substrate center and edge is reduced from 1.4 G to 0.79 G.

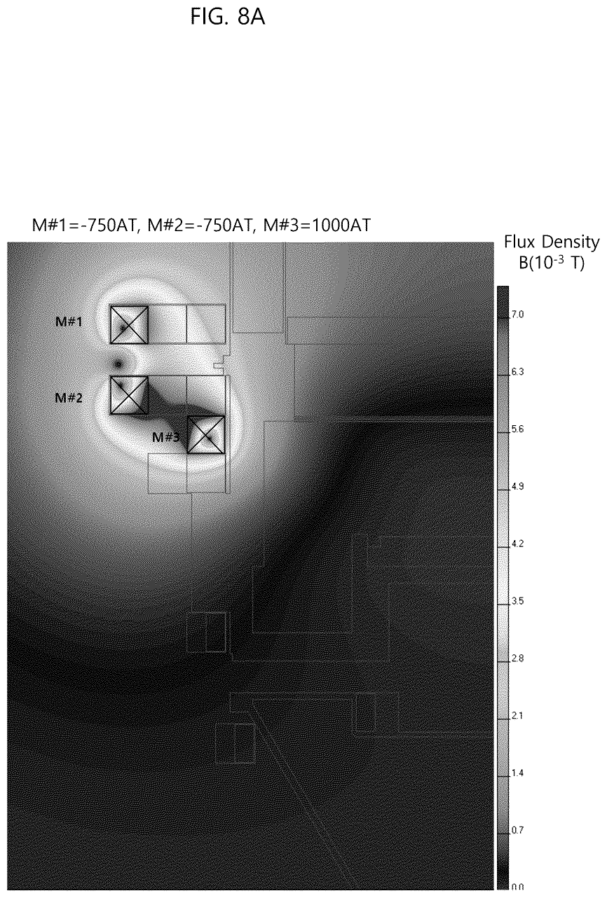

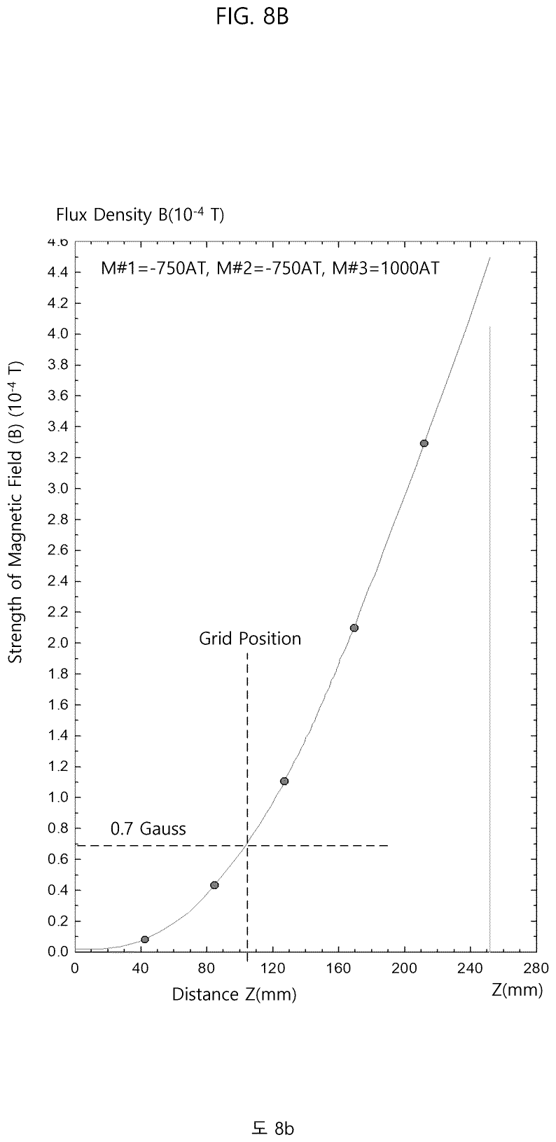

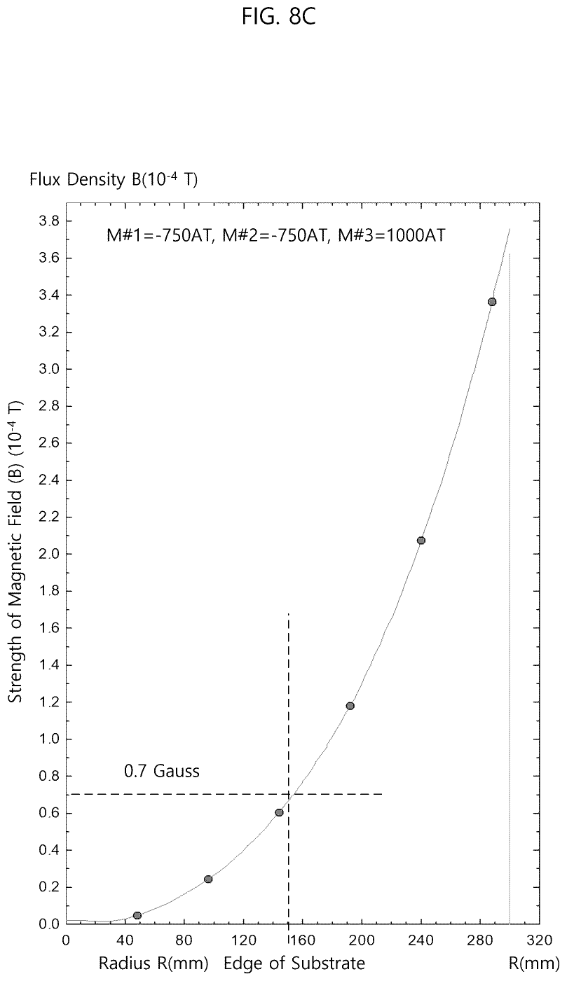

FIG. 8A is a computational simulation result illustrating a magnetic field distribution of a plasma processing device according to another embodiment of the present invention.

FIG. 8B is a graph illustrating the strength of a magnetic field along a z-axis based on the computational simulation result of FIG. 8A.

FIG. 8C is a graph illustrating the strength of a magnetic field with a radius based on the computational simulation result of FIG. 8A.

Referring to FIGS. 8A to 8C, a forward magnetic field generation unit 120 includes a first electromagnet (122) M #1 and a second electromagnet (124) M #2 and generates a forward magnetic field. The magnetic motive force (the product of current and the number of turns) of the first electromagnet (122) M #1 is −750 amperes (A), and the magnetic motive force (the product of current and the number of turns) of the second electromagnet (124) M #2 is −750 amperes (A).

A backward magnetic field generation unit 130 includes a third electromagnet M #3 and generates a backward magnetic field. The magnetic motive force (the product of current and the number of turns) of the third electromagnet M #3 is 1000 amperes (A).

The second electromagnet (124) M #2 and the third electromagnet M #3 are disposed close to each other. That is, the third electromagnet M #3 is disposed directly below an arrangement surface of the second electromagnet (124) M #2. When the grid 180 is disposed at the lower end of the third electromagnet M #3 of the backward magnetic field generation unit 130 (Z=106 mm), the strength of a magnetic field in the region above a wafer from the substrate S to the grid 180 is within approximately 0.7 G along a central axis of the substrate S.

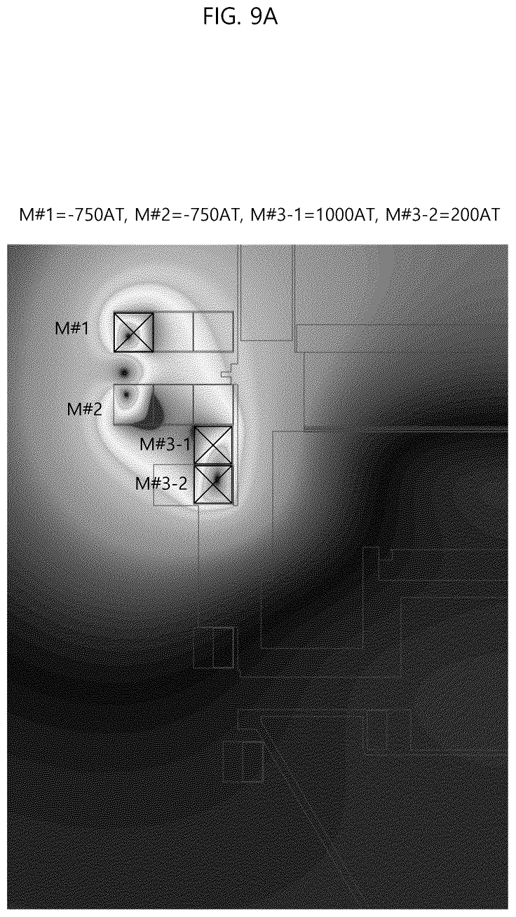

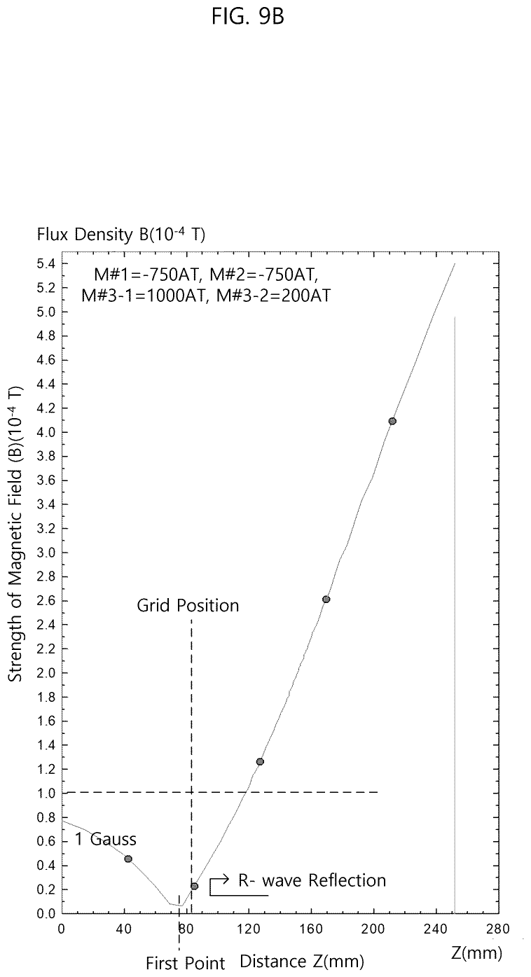

FIG. 9A is a computational simulation result illustrating a magnetic field distribution of a plasma processing device according to another embodiment of the present invention.

FIG. 9B is a graph illustrating the strength of a magnetic field along a z-axis based on the computational simulation result of FIG. 9A.

Referring to FIGS. 9A and 9B, a forward magnetic field generation unit 120 includes a first electromagnet (122) M #1 and a second electromagnet (124) M #2 and generates a forward magnetic field. The magnetic motive force (the product of current and the number of turns) of the first electromagnet (122) M #1 is −750 amperes (A), and the magnetic motive force (the product of current and the number of turns) of the second electromagnet (124) M #2 is −750 amperes (A).

A backward magnetic field generation unit 130 includes a (3-1)-th electromagnet M #3-1 and a (3-2)-th electromagnet M #3-2 disposed below the (3-1)-th electromagnet, and generates a backward magnetic field. The magnetic motive force (the product of current and the number of turns) of the (3-1)-th electromagnet M #3-1 is 1000 amperes (A). The magnetic motive force (the product of current and the number of turns) of the (3-2)-th electromagnet M #3-2 is 200 amperes (A).

The backward magnetic field generation unit 130 uses two adjacent electromagnets. A method of increasing the magnetic motive force of the backward magnetic field generation unit 130 is to increase the magnetic motive force of the third electromagnet M #3.

Alternatively, when an electromagnet for backward magnetic field generation M #3-2 is located (at z=57 mm to 62 mm, between the substrate and a lower end of the backward magnetic field electromagnet coil), the strength of the magnetic field in a region above a wafer from the substrate S to the grid 180 is within 0.7 G along a central axis of the substrate S to 100 mm from the substrate S. In this case, the backward magnetic field generation unit 130 uses two electromagnets. Therefore, it is preferable to align an optimal position of the grid 180 with a first point. However, the optimal position is preferably within ±10 mm with respect to the first point of the central axis of the substate S, considering the thickness of (a grid first grid, a second grid, a third grid, or the like), the number of electromagnets, and the degree of radial change at the first point caused by the arrangement of the electromagnet. Additionally, the position of the grid 180 within a range of 1 G may be determined with respect to the first point along the central axis of the substrate.

Although the present invention and its advantages have been described in detail, it should be understood that various changes, substitutions and alterations can be made herein without departing from the spirit and scope of the disclosure as defined by the following claims.

1. A plasma processing device comprising:
a chamber having a dielectric window provided in an upper surface thereof,
an antenna located above the dielectric window to generate plasma in an inner space of the chamber;
a substrate holder arranged inside the chamber such that a substrate is mounted thereon;
a forward magnetic field generation unit which is arranged outside of the chamber and includes an electromagnet provided outside the chamber between an arrangement surface of the antenna and an arrangement surface of the substrate;
a backward magnetic field generation unit which is arranged below the forward magnetic field generation unit and includes an electromagnet provided outside the chamber between the arrangement surface of the antenna and the arrangement surface of the substrate; and
a control unit for controlling current flowing in the forward magnetic field generation unit and current flowing in the backward magnetic field generation unit,
wherein:
the forward magnetic field generation unit generates a magnetic field directed in a forward direction from the antenna toward the substrate; and
the backward magnetic field generation unit generates a magnetic field directed in a backward direction from the substrate toward the antenna.

2. The plasma processing device as set forth in claim 1, wherein:
the control unit decreases an absolute value of the magnetic field to a first point in the backward direction with respect to a center of the substrate; and
the control unit increases the absolute value of the magnetic field in the backward direction from the first point.

3. The plasma processing device as set forth in claim 1, wherein:
the forward magnetic field generation unit includes a first electromagnet and a second electromagnet spaced apart from each other; and
the backward magnetic field generation unit includes a third electromagnet.

4. The plasma processing device as set forth in claim 1, wherein:
a diameter D1 of an electromagnet constituting the forward magnetic field generation unit is larger or smaller than a diameter D3 of an electromagnet constituting the backward magnetic field generation unit.

5. The plasma processing device as set forth in claim 1, wherein:
the control unit controls a ratio of a product of current and a number of coil turns (I1×N1+I2×N2) of an electromagnet constituting the forward magnetic field generation unit to a product of current and a number of coil turns (I3×N3) of an electromagnet constituting the backward magnetic field generation unit to be within a range of 1:0.5 to 1:0.9.

6. The plasma processing device as set forth in claim 1, further comprising:
an auxiliary electromagnet disposed at a position lower than an upper surface of the substrate holder,
wherein:
the control unit controls current of the auxiliary electromagnet.

7. The plasma processing device as set forth in claim 6, wherein:
a direction of a magnetic field generated by the auxiliary electromagnet is a forward direction.

8. The plasma processing device as set forth in claim 6, wherein:
the auxiliary electromagnet includes at least one of:
a first auxiliary electromagnet disposed outside the chamber between the upper surface and a lower surface of the substrate holder;
a second auxiliary electromagnet embedded in the substrate holder; and
a third auxiliary electromagnet disposed outside the chamber at a position lower than the lower surface of the substrate holder.

9. The plasma processing device as set forth in claim 7, wherein:
the control unit controls a ratio of a product of current and a number of coil turns (I3×N3) of an electromagnet constituting the backward magnetic field generation unit to a product of current and a number of coil turns (I4×N4) of the auxiliary electromagnet to be within a range of 1:0.01 to 1:0.3.

10. The plasma processing device as set forth in claim 2, wherein:
strength of the magnetic field in a space between the dielectric window and the upper surface of the substrate holder is 10 Gauss or less from a central axis of the substrate holder to the first point.

11. A plasma processing device comprising:
a chamber having a dielectric window provided in on an upper surface thereof,
a grid dividing an inner space of the chamber into an upper region and a lower region and extracting plasma from an upper region to a lower region;
an antenna located above the dielectric window to generate plasma in an inner space of the chamber;
a substrate holder arranged inside the chamber such that a substrate is mounted thereon;
a forward magnetic field generation unit including an electromagnet installed outside the chamber between an arrangement surface of the antenna and an arrangement surface of the substrate;
a backward magnetic field generation unit arranged below the forward magnetic field generation unit and including an electromagnet installed outside the chamber between the arrangement surface of the antenna and the arrangement surface of the substrate; and
a control unit controlling current flowing through the forward magnetic field generation unit and current flowing through the backward magnetic field generation unit,
wherein:
the forward magnetic field generation unit generates a magnetic field directed in a forward direction from the antenna toward the substrate; and
the backward magnetic field generation unit generates a magnetic field directed in a backward direction from the substrate toward the antenna.

12. The plasma processing device as set forth in claim 11, wherein:
the control unit decreases an absolute value of the magnetic field to a first point in the backward direction with respect to a center of the substrate; and
the control unit increases the absolute value of the magnetic field in the backward direction from the first point.

13. The plasma processing device as set forth in claim 12, wherein:
an arrangement surface of the grid is located at a position higher toward the dielectric window than the first point that is a region (or a point) in which the magnetic field is zero.
